(19) United States
(12) Patent Application Publication
(10) Pub. No.: US 2022/0037555 A1
(43) Pub. Date: Feb. 3, 2022

(54) MICRO LIGHT EMITTING DIODE, ARRAY SUBSTRATE, DISPLAY APPARATUS, AND METHOD OF FABRICATING ARRAY SUBSTRATE

(71) Applicants: BOE Technology Group Co., Ltd., Beijing (CN); Chengdu BOE Optoelectronics Technology Co., Ltd., Chengdu, Sichuan (CN)

(72) Inventors: Zhenhua Zhang, Beijing (CN); Yangpeng Wang, Beijing (CN)

(73) Assignees: BOE Technology Group Co., Ltd., Beijing (CN); Chengdu BOE Optoelectronics Technology Co., Ltd., Chengdu, Sichuan (CN)

(21) Appl. No.: 16/762,922

(22) PCT Filed: Jun. 21, 2019
(86) PCT No.: PCT/CN2019/092301

§ 371 Date: May 9, 2020

(51) Int. Cl. H01L 33/20; H01L 33/38; H01L 25/16; H01L 33/00; H01L 33/62; H01L 23/00

(52) U.S. Cl. CPC H01L 33/20; H01L 33/38; H01L 25/167; H01L 33/0075; H01L 33/04; H01L 33/62; H01L 24/81; H01L 24/95; H01L 33/0093

(57) ABSTRACT

A micro light emitting diode (micro LED) is provided. The micro LED includes a base substrate; a first electrode on the base substrate; a first type doped semiconductor layer on a side of the first electrode away from the base substrate; a quantum-well layer on a side of the first type doped semiconductor layer away from the first electrode; a second type doped semiconductor layer on a side of the quantum-well layer away from the first type doped semiconductor layer; and a second electrode on a side of the second type doped semiconductor layer away from the quantum-well layer.

### TECHNICAL FIELD

The present invention relates to display technology, more particularly, to a micro light emitting diode, an array substrate, a display apparatus, and a method of fabricating an array substrate.

### BACKGROUND

In recent years, miniaturized electro-optics devices are proposed and developed, including micro light emitting diode (micro LED). The micro LED-based display panels have the advantages of high brightness, high contrast ratio, fast response, and low power consumption. The micro LED-based display technology has found a wide range of applications in the display field, including smartphones and smart watches.

### SUMMARY

In one aspect, the present invention provides a micro light emitting diode (micro LED), comprising a base substrate; a first electrode on the base substrate; a first type doped semiconductor layer on a side of the first electrode away from the base substrate; a quantum-well layer on a side of the first type doped semiconductor layer away from the first electrode; a second type doped semiconductor layer on a side of the quantum-well layer away from the first type doped semiconductor layer; and a second electrode on a side of the second type doped semiconductor layer away from the quantum-well layer; wherein an orthographic projection of the first type doped semiconductor layer on the base substrate covers, and has an area greater than, an orthographic projection of the first electrode on the base substrate; an orthographic projection of the quantum-well layer on the base substrate covers, and has an area greater than, the orthographic projection of the first type doped semiconductor layer on the base substrate; an orthographic projection of the second type doped semiconductor layer on the base substrate covers, and has an area greater than, the orthographic projection of the quantum-well layer on the base substrate; and an orthographic projection of the second electrode on the base substrate covers, and has an area greater than, the orthographic projection of the second type doped semiconductor layer on the base substrate.

Optionally, a cross-section of the micro LED along a plane intersecting with, and substantially perpendicular to, each of the first electrode, the first type doped semiconductor layer, the quantum-well layer, the second type doped semiconductor layer, and the second electrode, has a substantially inverted trapezoidal shape.

Optionally, the micro LED further comprises a protection layer, wherein the protection layer is on at least one of perimeters of the first type doped semiconductor layer, the quantum-well layer, the second type doped semiconductor layer, and the second electrode.

Optionally, the protection layer is on each of outer peripheral sides of the first type doped semiconductor layer, the quantum-well layer, the second type doped semiconductor layer, and the second electrode.

Optionally, a first portion of the protection layer is on a side of the first electrode away from the quantum-well layer, and a second portion of the protection layer is on a side of the second electrode away from the quantum-well layer.

In another aspect, the present invention provides an array substrate, comprising: an array of a plurality of micro light emitting diodes (micro LEDs) on a base substrate; wherein a respective one of the plurality of micro LEDs comprises a first electrode on the base substrate; a first type doped semiconductor layer on a side of the first electrode away from the base substrate; a quantum-well layer on a side of the first type doped semiconductor layer away from the first electrode; a second type doped semiconductor layer on a side of the quantum-well layer away from the first type doped semiconductor layer; and a second electrode on a side of the second type doped semiconductor layer away from the quantum-well layer; wherein an orthographic projection of the first type doped semiconductor layer on the base substrate covers, and has an area greater than, an orthographic projection of the first electrode on the base substrate; an orthographic projection of the quantum-well layer on the base substrate covers, and has an area greater than, the orthographic projection of the first type doped semiconductor layer on the base substrate; an orthographic projection of the second type doped semiconductor layer on the base substrate covers, and has an area greater than, the orthographic projection of the quantum-well layer on the base substrate; and an orthographic projection of the second electrode on the base substrate covers, and has an area greater than, the orthographic projection of the second type doped semiconductor layer on the base substrate.

Optionally, the array substrate further comprises a bonding pad in contact with the first electrode and between the first electrode and the base substrate; wherein a volume of the bonding pad is no more than a half of a total volume of the first electrode, the first type doped semiconductor layer, the quantum-well layer, the second type doped semiconductor layer, and the second electrode in the respective one of the plurality of micro LEDs.

Optionally, in the respective one of the plurality of micro LEDs, a cross-section of the micro LED along a plane intersecting with, and substantially perpendicular to, each of the first electrode, the first type doped semiconductor layer, the quantum-well layer, the second type doped semiconductor layer, and the second electrode, has a substantially inverted trapezoidal shape.

Optionally, the array substrate further comprises an array of a plurality of thin film transistors on the base substrate; a pixel definition layer defining a plurality of subpixel apertures; an insulating layer on a side of the pixel definition layer away from the base substrate; and a common electrode layer on a side of the insulating layer away from the base substrate; wherein a drain electrode of a respective one of the plurality of thin film transistors is electrically connected to the first electrode of the respective one of the plurality of micro LEDs; and the common electrode layer is a unitary layer electrically connected to the second electrode of the respective one of the plurality of micro LEDs.

In another aspect, the present invention provides a display apparatus, comprising the array substrate described herein or fabricated by a method described herein, and one or more integrated circuits electrically connected to the array substrate.

In another aspect, the present invention provides a method of fabricating an array substrate, comprising forming a plurality of micro light emitting diodes (micro LEDs) on a base substrate; wherein forming a respective one of the plurality of micro LEDs comprises forming a first electrode on a base substrate; forming a first type doped semiconductor layer on a side of the first electrode away from the base substrate; forming a quantum-well layer on a side of the first type doped semiconductor layer away from the first electrode; forming a second type doped semiconductor layer on a side of the quantum-well layer away from the first type doped semiconductor layer; and forming a second electrode on a side of the second type doped semiconductor layer away from the quantum-well layer; wherein an orthographic projection of the first type doped semiconductor layer on the base substrate covers, and has an area greater than, an orthographic projection of the first electrode on the base substrate; an orthographic projection of the quantum-well layer on the base substrate covers, and has an area greater than, the orthographic projection of the first type doped semiconductor layer on the base substrate; an orthographic projection of the second type doped semiconductor layer on the base substrate covers, and has an area greater than, the orthographic projection of the quantum-well layer on the base substrate; and an orthographic projection of the second electrode on the base substrate covers, and has an area greater than, the orthographic projection of the second type doped semiconductor layer on the base substrate.

Optionally, prior to forming the plurality of micro LEDs, the method further comprises forming a first intermediate substrate by providing a growth layer; forming a second type doped semiconductor material layer on the growth layer; forming a quantum-well material layer on a side of the second type doped semiconductor material layer away from the growth layer; forming a first type doped semiconductor material layer on a side of the quantum-well material layer away from the second type doped semiconductor material layer; and forming a first electrode material layer on a side of the first type doped semiconductor material layer away from the quantum-well material layer.

Optionally, subsequent to forming the first intermediate substrate, the method further comprises attaching the first intermediate substrate to a support so that the first electrode material layer is attached to a surface of the support, and the growth layer is on a side of the first electrode material layer away from the support; removing the growth layer to expose a surface of second type doped semiconductor material layer; and forming a second electrode material layer on a side of the second type doped semiconductor material layer away from the quantum-well material layer, thereby forming a second intermediate substrate.

Optionally, the method further comprises etching the second intermediate substrate to form the plurality of micro LEDs; wherein the second intermediate substrate is etched so that an orthographic projection of the first type doped semiconductor layer on the support covers, and has an area greater than, an orthographic projection of the first electrode on the support; an orthographic projection of the quantum-well layer on the support covers, and has an area greater than, the orthographic projection of the first type doped semiconductor layer on the support; an orthographic projection of the second type doped semiconductor layer on the support covers, and has an area greater than, the orthographic projection of the quantum-well layer on the support; and an orthographic projection of the second electrode on the support covers, and has an area greater than, the orthographic projection of the second type doped semiconductor layer on the support.

Optionally, the support comprises a sacrificial layer, the first intermediate substrate is attached to the support so that the first electrode material layer is attached to a surface of the sacrificial layer, and the growth layer is on a side of the first electrode material layer away from the sacrificial layer; subsequent to etching the second intermediate substrate, the method further comprises etching the sacrificial layer to partially remove the sacrificial layer to form a reduced sacrificial layer, a portion of the sacrificial layer between adjacent micro LEDs of the plurality of micro LEDs is removed, an orthographic projection of the second electrode on the support covers, and has an area greater than, an orthographic projection of the reduced sacrificial layer on the support; and forming a protection layer covering substantially an entirety of perimeters of the first type doped semiconductor layer, the quantum-well layer, and the second type doped semiconductor layer, and at least partially covering the first electrode and the second electrode.

Optionally, the method further comprises forming a dense metal block on a side of the first electrode away from the support; wherein the dense metal block is electrically connected to the first electrode; and the dense metal block has a weight greater than at least twice of a total weight of the first electrode, the first type doped semiconductor layer, the quantum-well layer, the second type doped semiconductor layer, and the second electrode in the respective one of the plurality of micro LEDs; and a volume of the dense metal block is no more than a half of a total volume of the first electrode, the first type doped semiconductor layer, the quantum-well layer, the second type doped semiconductor layer, and the second electrode in the respective one of the plurality of micro LEDs.

Optionally, subsequent to forming the dense metal block, the method further comprises removing the plurality of micro LEDs from the support; providing a target substrate; and disposing the plurality of micro LEDs onto the target substrate.

Optionally, disposing the plurality of micro LEDs onto the target substrate comprises providing a guide plate over the target substrate, the guide plate having a plurality of openings respectively aligned with a plurality of target regions in the target substrate; and disposing the plurality of micro LEDs on the guide plate to guide the plurality of micro LEDs respectively through the plurality of openings and onto the plurality of target regions.

Optionally, the respective one of the plurality of micro LEDs is disposed onto the target substrate so that the dense metal block is in direct contact with a contact pad in a respective one of the plurality of target regions in the target substrate.

Optionally, the method further comprises heating the target substrate to convert the dense metal block into a bonding pad soldered with the contact pad; wherein the bonding pad is in direct contact with the first electrode and between the first electrode and the target substrate; and a volume of the bonding pad is no more than a half of a total volume of the first electrode, the first type doped semiconductor layer, the quantum-well layer, the second type doped semiconductor layer, and the second electrode in the respective one of the plurality of micro LEDs.

Optionally, a misplaced micro LED of the plurality of micro LEDs is disposed so that a dense metal block of the misplaced micro LED is not in direct contact with a contact pad in a corresponding one of the plurality of target regions; and subsequent to heating the target substrate, the method further comprises removing the misplaced micro LED from the target substrate.

In another aspect, the present invention provides a display substrate, comprising an array substrate fabricated by the method described herein, and one or more integrated circuits connected to the array substrate.

### BRIEF DESCRIPTION OF THE FIGURES

The following drawings are merely examples for illustrative purposes according to various disclosed embodiments and are not intended to limit the scope of the present invention.

FIG. 1 is a cross-sectional view of a micro light emitting diode in some embodiments according to the present disclosure.

FIG. 2 is a schematic representation of a cross-section of a micro light emitting diode in some embodiments according to the present disclosure.

FIG. 3 is a cross-sectional view of an array substrate in some embodiments according to the present disclosure.

FIG. 4 is a zoom-in view of a structure surrounding a respective one of a plurality of micro light emitting diodes in an array substrate in some embodiments according to the present disclosure,

FIGS. 5A to 5N illustrate a method of fabricating an array substrate in some embodiments according to the present disclosure.

FIGS. 6A to 6F illustrate a method of fabricating an array substrate in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

In fabricating a micro light emitting diode (micro LED) display panel, each of the micro LED has to be transferred from a growth substrate to a target substrate. Considering the display panel includes thousands to millions of micro LEDs, a pick-and-place transfer process is extremely time-consuming, and thus not suitable for large-scale fabrication of micro LED display panels. An improvement to the pick-and-place transfer is to use a printing head for transferring a plurality of micro LEDs at one time. Still, a process of transferring a large number of micro LEDs using a printing head is too complicated and time-consuming. Moreover, misalignment between the micro LEDs and the bonding contacts in the target substrate occurs frequently in the pick-and-place transfer or the transfer process using a printing head, resulting in defects in the display panel.

Accordingly, the present disclosure provides, inter alia, a micro light emitting diode, an array substrate, a display apparatus, and a method of fabricating an array substrate that substantially obviate one or more of the problems due to limitations and disadvantages of the related art. In one aspect, the present disclosure provides a micro light emitting diode (micro LED). In some embodiments, the micro light emitting diode includes a base substrate; a first electrode on the base substrate; a first type doped semiconductor layer on a side of the first electrode away from the base substrate; a quantum-well layer on a side of the first type doped semiconductor layer away from the first electrode; a second type doped semiconductor layer on a side of the quantum-well layer away from the first type doped semiconductor layer; and a second electrode on a side of the second type doped semiconductor layer away from the quantum-well layer. Optionally, an orthographic projection of the first type doped semiconductor layer on the base substrate covers, and has an area greater than, an orthographic projection of the first electrode on the base substrate. Optionally, an orthographic projection of the quantum-well layer on the base substrate covers, and has an area greater than, the orthographic projection of the first type doped semiconductor layer on the base substrate. Optionally, an orthographic projection of the second type doped semiconductor layer on the base substrate covers, and has an area greater than, the orthographic projection of the quantum-well layer on the base substrate. Optionally, an orthographic projection of the second electrode on the base substrate covers, and has an area greater than, the orthographic projection of the second type doped semiconductor layer on the base substrate. Optionally, the base substrate is a base substrate of an array substrate having a plurality of thin film transistors. Optionally, the first type doped semiconductor layer is a p-doped semiconductor layer, and the second type doped semiconductor layer is an n-doped semiconductor layer. Optionally, the first type doped semiconductor layer is an n-doped semiconductor layer, and the second type doped semiconductor layer is a p-doped semiconductor layer. Optionally, the p-doped semiconductor layer is p-doped GaN layer, and the n-doped semiconductor layer is an n-doped GaN layer.

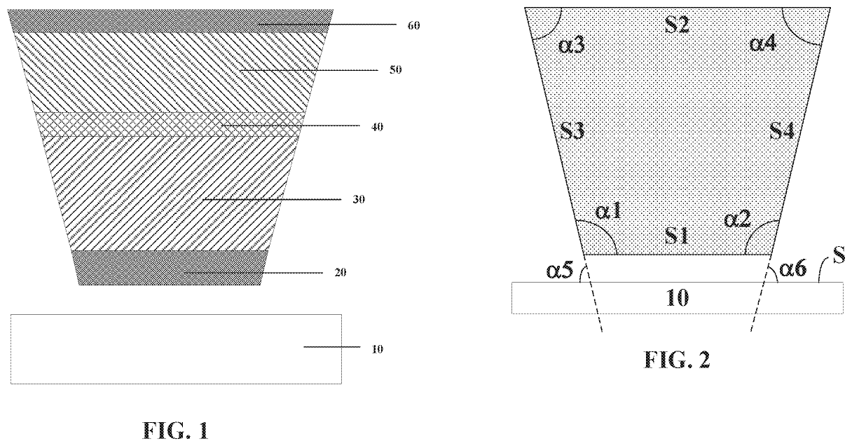

FIG. 1 is a cross-sectional view of a micro light emitting diode in some embodiments according to the present disclosure. Referring to FIG. 1, the micro LED in some embodiments includes a base substrate 10; a first electrode 20 on the base substrate 10; a first type doped semiconductor layer 30 on a side of the first electrode 20 away from the base substrate 10; a quantum-well layer 40 (e.g., a multiple quantum wells layer) on a side of the first type doped semiconductor layer 30 away from the first electrode 20; a second type doped semiconductor layer 50 on a side of the quantum-well layer 40 away from the first type doped semiconductor layer 30; and a second electrode 60 on a side of the second type doped semiconductor layer 50 away from the quantum-well layer 40. Optionally, an orthographic projection of the first type doped semiconductor layer 30 on the base substrate 10 covers, and has an area greater than, an orthographic projection of the first electrode 20 on the base substrate 10. Optionally, an orthographic projection of the quantum-well layer 40 on the base substrate 10 covers, and has an area greater than, the orthographic projection of the first type doped semiconductor layer 30 on the base substrate 10. Optionally, an orthographic projection of the second type doped semiconductor layer 50 on the base substrate 10 covers, and has an area greater than, the orthographic projection of the quantum-well layer 40 on the base substrate 10. Optionally, an orthographic projection of the second electrode 60 on the base substrate 10 covers, and has an area greater than, the orthographic projection of the second type doped semiconductor layer 50 on the base substrate 10.

FIG. 1 is a cross-section view along a plane intersecting with, and substantially perpendicular to, each of the first electrode 20, the first type doped semiconductor layer 30, the quantum-well layer 40, the second type doped semiconductor layer 50, and the second electrode 60. The cross-section may have various appropriate shapes. FIG. 2 is a schematic representation of a cross-section of a micro light emitting diode in some embodiments according to the present disclosure. Referring to FIG. 2, the cross-section has a first side Si closer to the base substrate 10, a second side S2 opposite to the first side S1 and on a side of the first side away from the base substrate 10, a third side S3 connecting the first side S1 and the second side S2, and a fourth side S4 connecting the first side S1 and the second side S2. The third side S3 and the fourth side S4 are lateral sides of the cross-section. The second side S2 is greater than the first side S1. Optionally, a first included angle α1 formed between the first side S1 and the third side S3 is an obtuse angle. Optionally, a second included angle α2 formed between the first side S1 and the fourth side S4 is an obtuse angle. Optionally, a third included angle α3 formed between the second side S2 and the third side S3 is an acute angle. Optionally, a fourth included angle α4 formed between the second side S2 and the fourth side S4 is an acute angle. Optionally, a fifth included angle α5 formed between the third side S3 and a surface S of the base substrate 10 is an acute angle. Optionally, a sixth included angle α6 formed between the fourth side S4 and a surface S of the base substrate 10 is an acute angle. In one example, as shown in FIG. 1, a cross-section of the micro LED along a plane intersecting with, and substantially perpendicular to, each of the first electrode 20, the first type doped semiconductor layer 30, the quantum-well layer 40, the second type doped semiconductor layer 50, and the second electrode 60, has a substantially inverted trapezoidal shape. The shape of the cross-section, however, is not limited to a substantially inverted trapezoidal shape.

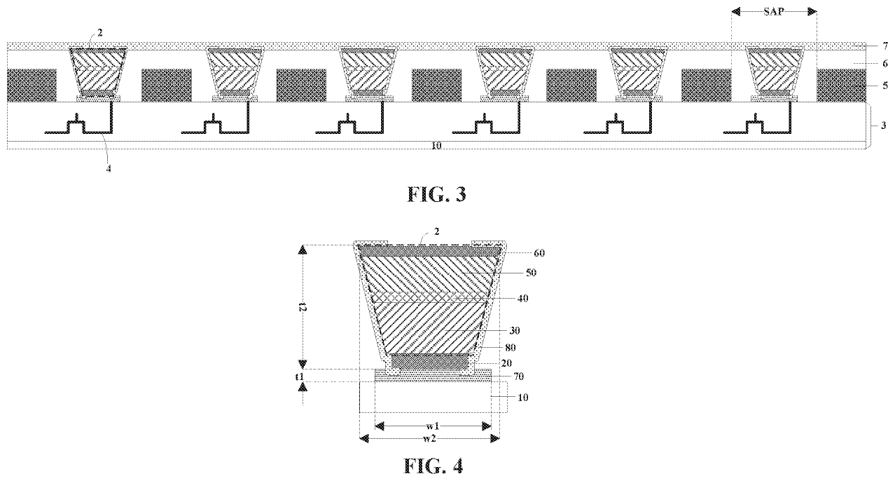

FIG. 3 is a cross-sectional view of an array substrate in some embodiments according to the present disclosure. FIG. 4 is a zoom-in view of a structure surrounding a respective one of a plurality of micro light emitting diodes in an array substrate in some embodiments according to the present disclosure. Referring to FIG. 3, the array substrate in some embodiments includes a plurality of micro light emitting diodes 2. Referring to FIG. 1 and FIG. 2, a respective one of the plurality of micro light emitting diodes 2 in some embodiments includes a base substrate 10; a first electrode 20 on the base substrate 10; a first type doped semiconductor layer 30 on a side of the first electrode 20 away from the base substrate 10; a quantum-well layer 40 on a side of the first type doped semiconductor layer 30 away from the first electrode 20; a second type doped semiconductor layer 50 on a side of the quantum-well layer 40 away from the first type doped semiconductor layer 30; and a second electrode 60 on a side of the second type doped semiconductor layer 50 away from the quantum-well layer 40. Optionally, an orthographic projection of the first type doped semiconductor layer 30 on the base substrate 10 covers, and has an area greater than, an orthographic projection of the first electrode 20 on the base substrate 10. Optionally, an orthographic projection of the quantum-well layer 40 on the base substrate 10 covers, and has an area greater than, the orthographic projection of the first type doped semiconductor layer 30 on the base substrate 10. Optionally, an orthographic projection of the second type doped semiconductor layer 50 on the base substrate 10 covers, and has an area greater than, the orthographic projection of the quantum-well layer 40 on the base substrate 10. Optionally, an orthographic projection of the second electrode 60 on the base substrate 10 covers, and has an area greater than, the orthographic projection of the second type doped semiconductor layer 50 on the base substrate 10.

Referring to FIG. 3 and FIG. 4, in some embodiments, the respective one of the plurality of micro light emitting diodes 2 further includes a bonding pad 70 in direct contact with the first electrode 20 and between the first electrode 20 and the base substrate 10. Optionally, a volume of the bonding pad 70 is no more than (e.g., no more than 90% of, no more than 80% of, no more than 70% of, no more than 60% of, no more than 50% of, no more than 40% of, no more than 30% of, no more than 20% of, no more than 10% of, no more than 5% of, or no more than 1% of) a total volume of the first electrode 20, the first type doped semiconductor layer 30, the quantum-well layer 40, the second type doped semiconductor layer 50, and the second electrode 60 in the respective one of the plurality of micro LEDs 2. Optionally, the volume of the bonding pad 70 is no more than a half of the total volume of the first electrode 20, the first type doped semiconductor layer 30, the quantum-well layer 40, the second type doped semiconductor layer 50, and the second electrode 60 in the respective one of the plurality of micro LEDs 2. Optionally, the volume of the bonding pad 70 is no more than a quarter of the total volume of the first electrode 20, the first type doped semiconductor layer 30, the quantum-well layer 40, the second type doped semiconductor layer 50, and the second electrode 60 in the respective one of the plurality of micro LEDs 2.

Optionally, the bonding pad 70 has a weight greater than (e.g., more than 1.1 times of, more than 2 times of, more than 3 times of, more than 4 times of, more than 5 times of, more than 6 times of, more than 7 times of, more than 8 times of, more than 9 times of, more than 10 times of, or more than 20 times of) a total weight of the first electrode 20, the first type doped semiconductor layer 30, the quantum-well layer 40, the second type doped semiconductor layer 50, and the second electrode 60 in the respective one of the plurality of micro LEDs 2. Optionally, the bonding pad 70 has a weight greater than at least twice of the total weight of the first electrode 20, the first type doped semiconductor layer 30, the quantum-well layer 40, the second type doped semiconductor layer 50, and the second electrode 60 in the respective one of the plurality of micro LEDs 2.

Optionally, a first thickness t1 of the bonding pad 70 is no more than (e.g., no more than 90% of, no more than 80% of, no more than 70% of, no more than 60% of, no more than 50% of, no more than 40% of, no more than 30% of, no more than 20% of, no more than 10% of, no more than 5% of, or no more than 1% of) a total thickness t2 of the first electrode 20, the first type doped semiconductor layer 30, the quantum-well layer 40, the second type doped semiconductor layer 50, and the second electrode 60 in the respective one of the plurality of micro LEDs 2. The first thickness t1 refers to a thickness of the bonding pad 70 along a direction substantially perpendicular to each of the first electrode 20, the first type doped semiconductor layer 30, the quantum-well layer 40, the second type doped semiconductor layer 50, and the second electrode 60 in the respective one of the plurality of micro LEDs 2. Similarly, the total thickness t2 is a thickness with respect to the direction substantially perpendicular to each of the first electrode 20, the first type doped semiconductor layer 30, the quantum-well layer 40, the second type doped semiconductor layer 50, and the second electrode 60 in the respective one of the plurality of micro LEDs 2. Optionally, the first thickness t1 of the bonding pad 70 is no more than a half of the total thickness t2 of the first electrode 20, the first type doped semiconductor layer 30, the quantum-well layer 40, the second type doped semiconductor layer 50, and the second electrode 60 in the respective one of the plurality of micro LEDs 2. Optionally, the first thickness t1 of the bonding pad 70 is no more than a quarter of the total thickness t2 of the first electrode 20, the first type doped semiconductor layer 30, the quantum-well layer 40, the second type doped semiconductor layer 50, and the second electrode 60 in the respective one of the plurality of micro LEDs 2.

Optionally, a first width w1 of the bonding pad 70 is no more than (e.g., no more than 90% of, no more than 80% of, no more than 70% of, no more than 60% of, no more than 50% of, no more than 40% of, no more than 30% of, no more than 20% of, no more than 10% of, no more than 5% of, or no more than 1% of) a maximum width w2 of the respective one of the plurality of micro LEDs 2 (e.g., a maximum width among the first electrode 20, the first type doped semiconductor layer 30, the quantum-well layer 40, the second type doped semiconductor layer 50, and the second electrode 60 in the respective one of the plurality of micro LEDs 2). The first width w1 refers to a width of the bonding pad 70 along a direction substantially parallel to an interface between the first electrode 20 and the bonding pad 70. Similarly, the maximum width w2 is a thickness with respect to the direction substantially parallel to an interface between the first electrode 20 and the bonding pad 70. Optionally, the first width w1 of the bonding pad 70 is no more than a half of the maximum width w2 of the respective one of the plurality of micro LEDs 2 (e.g., a maximum width among the first electrode 20, the first type doped semiconductor layer 30, the quantum-well layer 40, the second type doped semiconductor layer 50, and the second electrode 60 in the respective one of the plurality of micro LEDs 2). Optionally, the first width w1 of the bonding pad 70 is no more than a quarter of the maximum width w2 of the respective one of the plurality of micro LEDs 2 (e.g., a maximum width among the first electrode 20, the first type doped semiconductor layer 30, the quantum-well layer 40, the second type doped semiconductor layer 50, and the second electrode 60 in the respective one of the plurality of micro LEDs 2).

Referring to FIG. 3 and FIG. 4 again, in some embodiments, the array substrate further includes a protection layer 80 covering substantially an entirety of perimeters of the first type doped semiconductor layer 30, the quantum-well layer 40, and the second type doped semiconductor layer 50, and at least partially covering the first electrode 20 and the second electrode 60. Optionally, the protection layer 80 covers an entirety of perimeters of the first electrode 20 and the second electrode 60. Optionally, the protection layer 80 further covers a portion of a bottom surface of the first electrode 20. Optionally, the protection layer 80 further covers a portion of a top surface of the second electrode 60. Optionally, the protection layer 80 is on at least one of perimeters of the first type doped semiconductor layer 30, the quantum-well layer 40, the second type doped semiconductor layer 50, and the second electrode 60. Optionally, the protection layer 80 is on each of outer peripheral sides of the first type doped semiconductor layer 30, the quantum-well layer 40, the second type doped semiconductor layer 50, and the second electrode 60. Optionally, a first portion of the protection layer 80 is on a side of the first electrode 20 away from the quantum-well layer 40. Optionally, a second portion of the protection layer 80 is on a side of the second electrode 60 away from the quantum-well layer 40.

In some embodiments, the array substrate further includes an array of a plurality of thin film transistors 4 on the base substrate 10; a pixel definition layer 5 defining a plurality of subpixel apertures SAP; an insulating layer 6 on a side of the pixel definition layer 5 away from the base substrate 10; and a common electrode layer 7 on a side of the insulating layer 6 away from the base substrate 10. In one example, the base substrate 10 is a base substrate of a thin film transistor back plate 3. A drain electrode of a respective one of the plurality of thin film transistors 4 is electrically connected to the first electrode 20 of the respective one of the plurality of micro light emitting diodes 2. Optionally, as shown in FIG. 3, the common electrode layer 7 is a unitary layer electrically connected to the second electrode 60 of the respective one of the plurality of micro light emitting diodes 2.

In another aspect, the present disclosure provides a method of fabricating an array substrate. In some embodiments, the method includes forming a plurality of micro light emitting diodes (micro LEDs) on a base substrate. In some embodiments, forming a respective one of the plurality of micro LEDs includes forming a first electrode on a base substrate; forming a first type doped semiconductor layer on a side of the first electrode away from the base substrate; forming a quantum-well layer on a side of the first type doped semiconductor layer away from the first electrode; forming a second type doped semiconductor layer on a side of the quantum-well layer away from the first type doped semiconductor layer; and forming a second electrode on a side of the second type doped semiconductor layer away from the quantum-well layer. Optionally, an orthographic projection of the first type doped semiconductor layer on the base substrate covers, and has an area greater than, an orthographic projection of the first electrode on the base substrate. Optionally, an orthographic projection of the quantum-well layer on the base substrate covers, and has an area greater than, the orthographic projection of the first type doped semiconductor layer on the base substrate. Optionally, an orthographic projection of the second type doped semiconductor layer on the base substrate covers, and has an area greater than, the orthographic projection of the quantum-well layer on the base substrate. Optionally, an orthographic projection of the second electrode on the base substrate covers, and has an area greater than, the orthographic projection of the second type doped semiconductor layer on the base substrate.

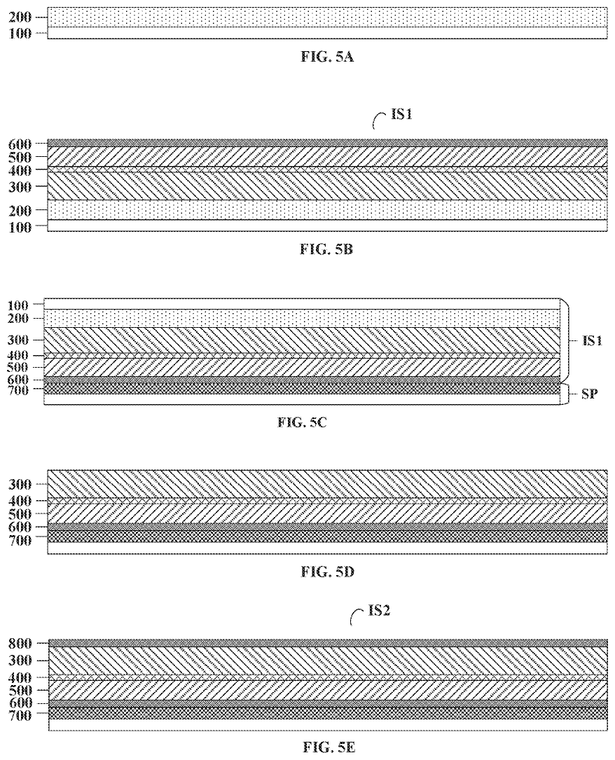

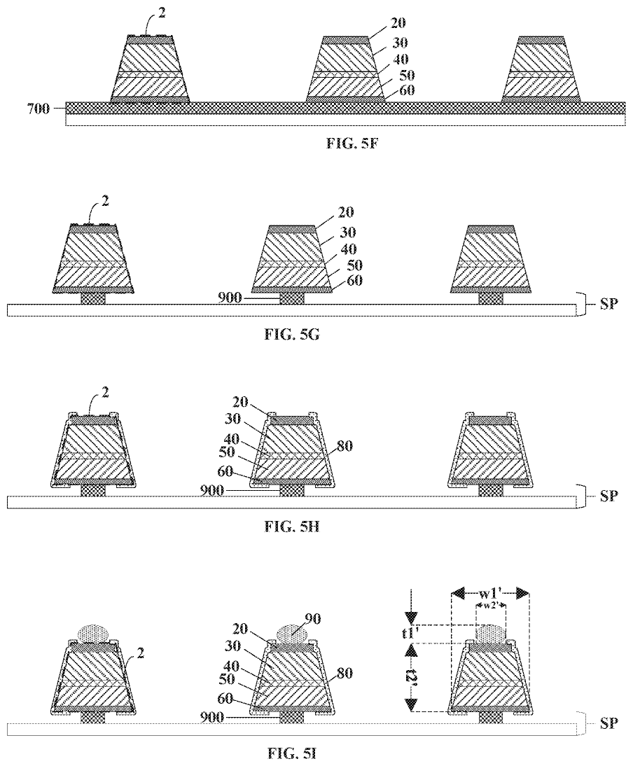

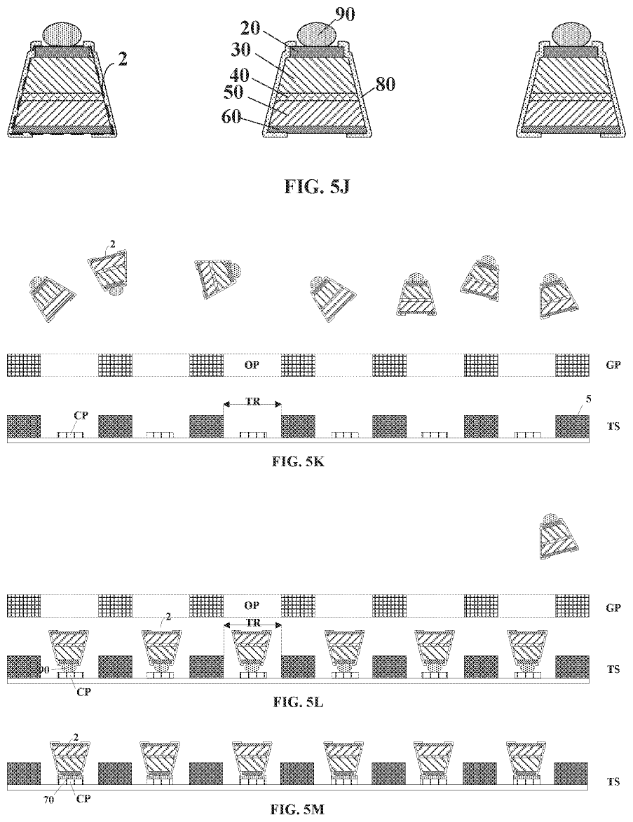

FIGS. 5A to 5N illustrate a method of fabricating an array substrate in some embodiments according to the present disclosure. Referring to FIG. 5A, the method in some embodiments includes forming a growth layer 200 on a wafer 100. Optionally, the growth layer 200 is a gallium nitride (GaN) substrate for epitaxial growth of micro LED layers. Referring to FIG. 5B, the method further includes forming a second type doped semiconductor material layer 300 on the growth layer 200; forming a quantum-well material layer 400 on a side of the second type doped semiconductor material layer 300 away from the growth layer 200; forming a first type doped semiconductor material layer 500 on a side of the quantum-well material layer 400 away from the second type doped semiconductor material layer 300; and forming a first electrode material layer 600 on a side of the first type doped semiconductor material layer 500 away from the quantum-well material layer 400. A first intermediate substrate IS1 is formed.

Various appropriate materials may be used for making the growth layer 200. Examples of appropriate growth layer materials include silicon, sapphire, quartz, GaN, SiC, and alumina. In one example, the growth layer 200 is made of a semiconductor material such as silicon.

Referring to FIG. 5C, in some embodiments, the first intermediate substrate ISI is flipped and is attached to a support SR Specifically, subsequent to forming the first intermediate substrate IS1, the method further includes attaching the first intermediate substrate IS1 to a support SP so that the first electrode material layer 600 is attached to a surface of the support SP, and the growth layer 200 is on a side of the first electrode material layer 600 away from the support SP. Optionally, as shown in FIG. 5C, the support SP includes a sacrificial layer 700, the first intermediate substrate IS1 is attached to the support SP so that the first electrode material layer 600 is attached to a surface of the sacrificial layer 700, and the growth layer 200 is on a side of the first electrode material layer 600 away from the sacrificial layer 700.

Referring to FIG. 5D, the method in sonic embodiments further includes removing the wafer 100, and removing the growth layer 200 (e.g., by etching) to expose a surface of second type doped semiconductor material layer 300.

Referring to FIG. 5E, the method in some embodiments further includes forming a second electrode material layer 800 on a side of the second type doped semiconductor material layer 300 away from the quantum-well material layer 400, thereby forming a second intermediate substrate IS2.

Referring to FIG. 5E and FIG. 5F, the method in some embodiments further includes etching the second intermediate substrate IS2 to form the plurality of Micro light emitting diodes 2. Various appropriate etching methods may be used for etching the second intermediate substrate IS2. Examples of etching methods include, but are not limited to, reactive ion etching (RIE), deep reactive ion etching (DRIE), inductively coupled plasma etching (ICP), electron cyclotron resonance etching (ECR), ion beam etching, and laser machining. Various etching gas may be used for dry etching. Examples of plasma etching gas include, but are not limited to, boron chloride (BCl₃) and chlorine (Cl₂). In some embodiments, the step of etching the second intermediate substrate IS2 is performed using an inductively coupled plasma etching process. Examples of plasma etching gas for performing the inductively coupled plasma etching process includes boron chloride (BCl₃), carbon fluoride (CF₄), and chlorine (Cl₂).

Optionally, the second intermediate substrate IS2 is etched so that an orthographic projection of the first type doped semiconductor layer 30 on the base substrate 10 covers, and has an area greater than, an orthographic projection of the first electrode 20 on the base substrate 10. Optionally, the second intermediate substrate IS2 is etched so that an orthographic projection of the quantum-well layer 40 on the base substrate 10 covers, and has an area greater than, the orthographic projection of the first type doped semiconductor layer 30 on the base substrate 10. Optionally, the second intermediate substrate IS2 is etched so that an orthographic projection of the second type doped semiconductor layer 50 on the base substrate 10 covers, and has an area greater than, the orthographic projection of the quantum-well layer 40 on the base substrate 10. Optionally, the second intermediate substrate IS2 is etched so that an orthographic projection of the second electrode 60 on the base substrate 10 covers, and has an area greater than, the orthographic projection of the second type doped semiconductor layer 50 on the base substrate 10.

Referring to FIG. 5F and FIG. 5G, in some embodiments, subsequent to etching the second intermediate substrate IS2, the method further includes etching the sacrificial layer 700 to partially remove the sacrificial layer 700 to form a reduced sacrificial layer 900. As shown in FIG. 5F and FIG. 5G, a portion of the sacrificial layer 700 between adjacent micro light emitting diodes of the plurality of micro light emitting diodes 2 is removed. Optionally, an orthographic projection of the second electrode 60 on the support SP covers, and has an area greater than, an orthographic projection of the reduced sacrificial layer 900 on the support SP. Etching the sacrificial layer 700 into the reduced sacrificial layer 900 makes it easier to remove the plurality of micro light emitting diodes 2 from the support SP in a subsequent process.

Referring to FIG. 5H, in some embodiments, the method further includes forming a protection layer 80 to cover substantially an entirety of perimeters of the first type doped semiconductor layer 30, the quantum-well layer 40, and the second type doped semiconductor layer 50, and at least partially covering the first electrode 20 and the second electrode 60. Optionally, the protection layer 80 is formed to cover an entirety of perimeters of the first electrode 20 and the second electrode 60. Optionally, the protection layer 80 is formed to further cover a portion of a bottom surface of the first electrode 20. Optionally, the protection layer 80 is formed to further cover a portion of a top surface of the second electrode 60. Optionally, the protection layer 80 is formed on at least one of perimeters of the first type doped semiconductor layer 30, the quantum-well layer 40, the second type doped semiconductor layer 50, and the second electrode 60. Optionally, the protection layer 80 is formed on each of outer peripheral sides of the first type doped semiconductor layer 30, the quantum-well layer 40, the second type doped semiconductor layer 50, and the second electrode 60. Optionally, a first portion of the protection layer 80 is formed on a side of the first electrode 20 away from the quantum-well layer 40. Optionally, a second portion of the protection layer 80 is formed on a side of the second electrode 60 away from the quantum-well layer 40.

Referring to FIG. 5I, in some embodiments, the method further includes forming a dense metal block 90 on a side of the first electrode 20 away from the support SP. The dense metal block 90 is formed to be electrically connected to the first electrode 20. Optionally, the dense metal block 90 has a weight greater than (e.g., more than 1.1 times of, more than 2 times of, more than 3 times of, more than 4 times of, more than 5 times of, more than 6 times of, more than 7 times of, more than 8 times of, more than 9 times of, more than 10 times of, or more than 20 times of) a total weight of the first electrode 20, the first type doped semiconductor layer 30, the quantum-well layer 40, the second type doped semiconductor layer 50, and the second electrode 60 in the respective one of the plurality of micro LEDs 2.

Optionally, the dense metal block 90 has a weight greater than at least twice of the total weight of the first electrode 20, the first type doped semiconductor layer 30, the quantum-well layer 40, the second type doped semiconductor layer 50, and the second electrode 60 in the respective one of the plurality of micro LEDs 2.

Optionally, a volume of the dense metal block 90 is no more than (e.g., no more than 90% of, no more than 80% of, no more than 70% of, no more than 60% of, no more than 50% of, no more than 40% of, no more than 30% of, no more than 20% of, no more than 10% of, no more than 5% of, or no more than 1% of) a total volume of the first electrode 20, the first type doped semiconductor layer 30, the quantum-well layer 40, the second type doped semiconductor layer 50, and the second electrode 60 in the respective one of the plurality of micro LEDs 2. Optionally, the volume of the dense metal block 90 is no more than a half of the total volume of the first electrode 20, the first type doped semiconductor layer 30, the quantum-well layer 40, the second type doped semiconductor layer 50, and the second electrode 60 in the respective one of the plurality of micro LEDs 2. Optionally, the volume of the dense metal block 90 is no more than a quarter of the total volume of the first electrode 20, the first type doped semiconductor layer 30, the quantum-well layer 40, the second type doped semiconductor layer 50, and the second electrode 60 in the respective one of the plurality of micro LEDs 2.

Optionally, a first thickness t1′ of the dense metal block 90 is no more than (e.g., no more than 90% of, no more than 80% of, no more than 70% of, no more than 60% of, no more than 50% of, no more than 40% of, no more than 30% of, no more than 20% of, no more than 10% of, no more than 5% of, or no more than 1% of) a total thickness t2′ of the first electrode 20, the first type doped semiconductor layer 30, the quantum-well layer 40, the second type doped semiconductor layer 50, and the second electrode 60 in the respective one of the plurality of micro LEDs 2. The first thickness t1′ refers to a thickness of the dense metal block 90 along a direction substantially perpendicular to each of the first electrode the first type doped semiconductor layer 30, the quantum-well layer 40, the second type doped semiconductor layer 50, and the second electrode 60 in the respective one of the plurality of micro LEDs 2. Similarly, the total thickness t2′ is a thickness with respect to the direction substantially perpendicular to each of the first electrode 20, the first type doped semiconductor layer 30, the quantum-well layer 40, the second type doped semiconductor layer 50, and the second electrode 60 in the respective one of the plurality of micro LEDs 2. Optionally, the first thickness t1′ of the dense metal block 90 is no more than a half of the total thickness t2′ of the first electrode 20, the first type doped semiconductor layer 30, the quantum-well layer 40, the second type doped semiconductor layer 50, and the second electrode 60 in the respective one of the plurality of micro LEDs 2. Optionally, the first thickness t1′ of the dense metal block 90 is no more than a quarter of the total thickness t2 of the first electrode 20, the first type doped semiconductor layer 30, the quantum-well layer 40, the second type doped semiconductor layer 50, and the second electrode 60 in the respective one of the plurality of micro LEDs 2.

Optionally, a first width w1′ of the dense metal block 90 is no more than (e.g., no more than 90% of, no more than 80% of, no more than 70% of, no more than 60% of, no more than 50% of, no more than 40% of, no more than 30% of, no more than 20% of, no more than 10% of, no more than 5% of, or no more than 1% of) a maximum width the respective one of the plurality of micro LEDs 2 (e.g., a maximum width among the first electrode 20, the first type doped semiconductor layer 30, the quantum-well layer 40, the second type doped semiconductor layer 50, and the second electrode 60 in the respective one of the plurality of micro LEDs 2). The first width w1 refers to a width of the dense metal block 90 along a direction substantially parallel to an interface between the first electrode 20 and the dense metal block 90. Similarly, the maximum width w2′ is a thickness with respect to the direction substantially parallel to an interface between the first electrode 20 and the dense metal block 90. Optionally, the first width w1′ of the dense metal block 90 is no more than a half of the maximum width w2′ of the respective one of the plurality of micro LEDs 2 (e.g., a maximum width among the first electrode 20, the first type doped semiconductor layer 30, the quantum-well layer 40, the second type doped semiconductor layer 50, and the second electrode 60 in the respective one of the plurality of micro LEDs 2). Optionally, the first width w1′ of the dense metal block 90 is no more than a quarter of the maximum width w2′ of the respective one of the plurality of micro LEDs 2 (e.g., a maximum width among the first electrode 20, the first type doped semiconductor layer 30, the quantum-well layer 40, the second type doped semiconductor layer 50, and the second electrode 60 in the respective one of the plurality of micro LEDs 2).

Referring to FIG. 5I and FIG. 5J, in some embodiments, the method further includes removing the plurality of micro LEDs 2 from the support SP, e.g., by etching the reduced sacrificial layer 900, or by using a lift-off method.

Referring to FIG. 5K and FIG. 5L, the method in some embodiments further includes providing a target substrate TS; and disposing the plurality of micro LEDs 2 onto the target substrate Th. Referring to FIG. 5K, the method in some embodiments includes providing a guide plate GP (e.g., a shaking sieve) over the target substrate TS, the guide plate GP having a plurality of openings OP respectively aligned with a plurality of target regions TR in the target substrate TS. Optionally, the plurality of target regions TR are defined by a pixel definition layer 5.

Referring to FIG. 5K and FIG. 5I, the method in some embodiments further includes disposing the plurality of micro LEDs 2 on the guide plate GP to guide the plurality of micro LEDs 2 respectively through the plurality of openings OP and onto the plurality of target regions TR. The respective one of the plurality of micro LEDs 2 is disposed onto the target substrate TS so that the dense metal block 90 is in direct contact with a contact pad CP in a respective one of the plurality of target regions TR in the target substrate TS.

Referring to FIG. 5L and FIG. 5M, the method in some embodiments further includes heating the target substrate TS to convert the dense metal block 90 into a bonding pad 70 soldered with the contact pad CP. The bonding pad 70 is in direct contact with the first electrode 20 and is between the first electrode 20 and the target substrate TS. Optionally, a volume of the bonding pad 70 is no more than (e.g., no more than 90% of, no more than 80% of, no more than 70% of, no more than 60% of, no more than 50% of, no more than 40% of, no more than 30% of, no more than 20% of, no more than 10% of, no more than 5% of, or no more than 1% of) a total volume of the first electrode 20, the first type doped semiconductor layer 30, the quantum-well layer 40, the second type doped semiconductor layer 50, and the second electrode 60 in the respective one of the plurality of micro LEDs 2. Optionally, the volume of the bonding pad 70 is no more than a half of the total volume of the first electrode 20, the first type doped semiconductor layer 30, the quantum-well layer 40, the second type doped semiconductor layer 50, and the second electrode 60 in the respective one of the plurality of micro LEDs 2. Optionally, the volume of the bonding pad 70 is no more than a quarter of the total volume of the first electrode 20, the first type doped semiconductor layer 30, the quantum-well layer 40, the second type doped semiconductor layer 50, and the second electrode 60 in the respective one of the plurality of micro LEDs 2.

Optionally, the bonding pad 70 has a weight greater than (e.g., more than 1.1 times of, more than 2 times of, more than 3 times of, more than 4 times of, more than 5 times of, more than 6 times of, more than 7 times of, more than 8 times of, more than 9 times of, more than 10 times of, or more than 20 times of) a total weight of the first electrode 20, the first type doped semiconductor layer 30, the quantum-well layer 40, the second type doped semiconductor layer 50, and the second electrode 60 in the respective one of the plurality of micro LEDs 2. Optionally, the bonding pad 70 has a weight greater than at least twice of the total weight of the first electrode 20, the first type doped semiconductor layer 30, the quantum-well layer 40, the second type doped semiconductor layer 50, and the second electrode 60 in the respective one of the plurality of micro LEDs 2. An array substrate is then formed.

Referring to FIG. 5N, the method in some embodiments further includes forming an insulating layer 6 on the plurality of micro LEDs 2; and a common electrode layer 7 on a side of the insulating layer 6 away from the plurality of micro LEDs 2. In one example, the target substrate TS is a thin film transistor array substrate. Optionally, as shown in FIG. 5N, the common electrode layer 7 is a unitary layer electrically connected to the respective one of the plurality of micro light emitting diodes 2.

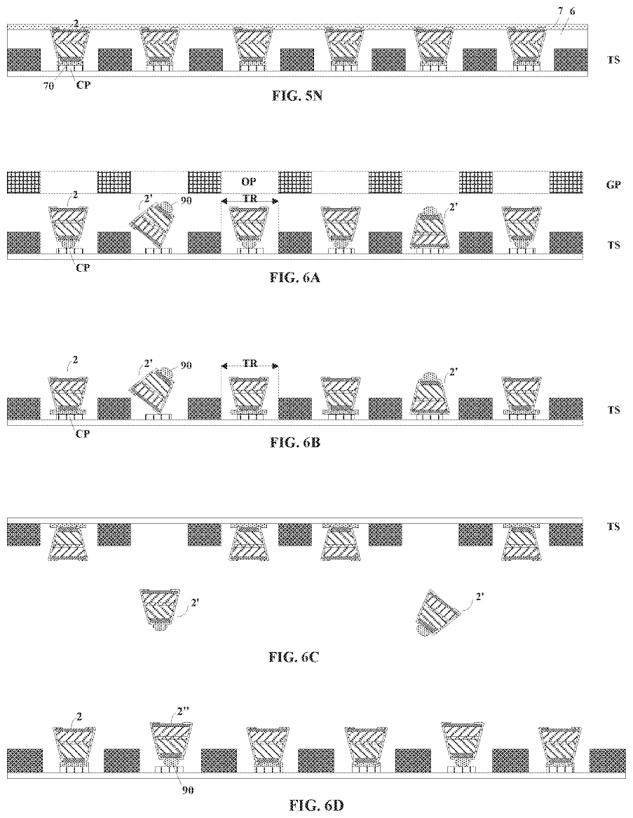

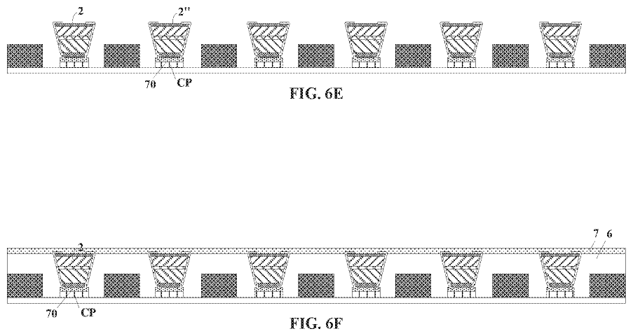

FIGS. 6A to 6F illustrate a method of fabricating an array substrate in some embodiments according to the present disclosure. Referring to FIG. 6A, in some embodiments, in the process of disposing the plurality of micro LEDs 2 onto the target substrate TS, some micro LEDs may be misplaced so that the dense metal block cannot be soldered with a contact pad. Optionally, as shown in FIG. 6A, a misplaced micro LED 2′ of the plurality of micro LEDs is disposed so that a dense metal block 90 of the misplaced micro LED 2′ is not in direct contact with a contact pad CP in a corresponding one of the plurality of target regions TR.

Referring to 6B, the target substrate TS is heated to convert the dense metal block 90 of the micro LEDs that are not misplaced into a bonding pad 70, and the bonding pad 70 is soldered with the contact pad CP. The bonding pad 70 is in direct contact with the first electrode 20 and is between the first electrode 20 and the target substrate TS. For the misplaced micro LED 2′, the dense metal block 90 of the misplaced micro LED 2′ is not in direct contact with the contact pad CP, and is not converted into the bonding pad 70.

In some embodiments, subsequent to heating the target substrate TS, the method further includes removing the misplaced micro LED 2′ from the target substrate TS. Referring to FIG. 6C, in one example, the target substrate TS is flipped upside down. Because the misplaced micro LED 2′ is not soldered with the contact pad, it falls off the target substrate TS.

Referring to FIG. 6D, in target regions missing micro LEDs, a replacement micro LED 2″ with a dense metal block 90 may be transferred, e.g., individually transferred, onto the target substrate TS.

Referring to FIG. 6E, the target substrate TS is heated again to convert the dense metal block 90 of the replacement micro LEDs 2″ into a bonding pad 70, and the bonding pad 70 is soldered with the contact pad CP. The bonding pad 70 is in direct contact with the first electrode 20 of the replacement micro LEDs 2″ and is between the first electrode 20 and the target substrate TS.

Referring to FIG. 6F, the method in some embodiments further includes forming an insulating layer 6 on the plurality of micro LEDs 2; and a common electrode layer 7 on a side of the insulating layer 6 away from the plurality of micro LEDs 2. In one example, the target substrate TS is a thin film transistor array substrate. Optionally, as shown in FIG. 5N, the common electrode layer 7 is a unitary layer electrically connected to the respective one of the plurality of micro light emitting diodes 2.

In another aspect, the present disclosure provides a display apparatus having the array substrate described herein or fabricated by a method described herein, or having the micro light emitting diode described herein or fabricated by a method described herein. Optionally, the display apparatus further includes one or more integrated circuits connected to the array substrate. Examples of appropriate display apparatuses include, but are not limited to, an electronic paper, a mobile phone, a tablet computer, a television, a monitor, a notebook computer, a digital album, a GPS, etc.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc, following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A micro light emitting diode (micro LED), comprising:
a base substrate;
a first electrode on the base substrate;
a first type doped semiconductor layer on a side of the first electrode away from the base substrate;
a quantum-well layer on a side of the first type doped semiconductor layer away from the first electrode;
a second type doped semiconductor layer on a side of the quantum-well layer away from the first type doped semiconductor layer; and
a second electrode on a side of the second type doped semiconductor layer away from the quantum-well layer;
wherein an orthographic projection of the first type doped semiconductor layer on the base substrate covers, and has an area greater than, an orthographic projection of the first electrode on the base substrate;
an orthographic projection of the quantum-well layer on the base substrate covers, and has an area greater than, the orthographic projection of the first type doped semiconductor layer on the base substrate;
an orthographic projection of the second type doped semiconductor layer on the base substrate covers, and has an area greater than, the orthographic projection of the quantum-well layer on the base substrate; and
an orthographic projection of the second electrode on the base substrate covers, and has an area greater than, the orthographic projection of the second type doped semiconductor layer on the base substrate.

2. The micro LED of claim 1, wherein a cross-section of the micro LED along a plane intersecting with, and substantially perpendicular to, each of the first electrode, the first type doped semiconductor layer, the quantum-well layer, the second type doped semiconductor layer, and the second electrode, has a substantially inverted trapezoidal shape.

3. The micro LED of claim 1, further comprising a protection layer, wherein the protection layer is on at least one of perimeters of the first type doped semiconductor layer, the quantum-well layer, the second type doped semiconductor layer, and the second electrode.

4. The micro LED of claim 3, wherein the protection layer is on each of outer peripheral sides of the first type doped semiconductor layer, the quantum-well layer, the second type doped semiconductor layer, and the second electrode.

5. The micro LED of claim 4, wherein a first portion of the protection layer is on a side of the first electrode away from the quantum-well layer, and a second portion of the protection layer is on a side of the second electrode away from the quantum-well layer.

6. An array substrate, comprising: an array of a plurality of micro light emitting diodes (micro LEDs) on a base substrate;
wherein a respective one of the plurality of micro LEDs comprises:
a first electrode on the base substrate;
a first type doped semiconductor layer on a side of the first electrode away from the base substrate;
a quantum-well layer on a side of the first type doped semiconductor layer away from the first electrode;
a second type doped semiconductor layer on a side of the quantum-well layer away from the first type doped semiconductor layer; and
a second electrode on a side of the second type doped semiconductor layer away from the quantum-well layer;
wherein an orthographic projection of the first type doped semiconductor layer on the base substrate covers, and has an area greater than, an orthographic projection of the first electrode on the base substrate;
an orthographic projection of the quantum-well layer on the base substrate covers, and has an area greater than, the orthographic projection of the first type doped semiconductor layer on the base substrate;
an orthographic projection of the second type doped semiconductor layer on the base substrate covers, and has an area greater than, the orthographic projection of the quantum-well layer on the base substrate; and
an orthographic projection of the second electrode on the base substrate covers, and has an area greater than, the orthographic projection of the second type doped semiconductor layer on the base substrate.

7. The array substrate of claim 6, further comprising a bonding pad in contact with the first electrode and between the first electrode and the base substrate;
wherein a volume of the bonding pad is no more than a half of a total volume of the first electrode, the first type doped semiconductor layer, the quantum-well layer, the second type doped semiconductor layer, and the second electrode in the respective one of the plurality of micro LEDs.

8. The array substrate of claim 6, wherein, in the respective one of the plurality of micro LEDs, a cross-section of the micro LED along a plane intersecting with, and substantially perpendicular to, each of the first electrode, the first type doped semiconductor layer, the quantum-well layer, the second type doped semiconductor layer, and the second electrode, has a substantially inverted trapezoidal shape.

9. The array substrate of claim 6, further comprising
an array of a plurality of thin film transistors on the base substrate;
a pixel definition layer defining a plurality of subpixel apertures;
an insulating layer on a side of the pixel definition layer away from the base substrate; and
a common electrode layer on a side of the insulating layer away from the base substrate;
wherein a drain electrode of a respective one of the plurality of thin film transistors is electrically connected to the first electrode of the respective one of the plurality of micro LEDs; and
the common electrode layer is a unitary layer electrically connected to the second electrode of the respective one of the plurality of micro LEDs.

10. A display apparatus, comprising the array substrate of claim 6, and one or more integrated circuits electrically connected to the array substrate.

11. A method of fabricating an array substrate, comprising:
forming a plurality of micro light emitting diodes (micro LEDs) on a base substrate;
wherein forming a respective one of the plurality of micro LEDs comprises:
forming a first electrode on a base substrate;
forming a first type doped semiconductor layer on a side of the first electrode away from the base substrate;
forming a quantum-well layer on a side of the first type doped semiconductor layer away from the first electrode;
forming a second type doped semiconductor layer on a side of the quantum-well layer away from the first type doped semiconductor layer; and
forming a second electrode on a side of the second type doped semiconductor layer away from the quantum-well layer;
wherein an orthographic projection of the first type doped semiconductor layer on the base substrate covers, and has an area greater than, an orthographic projection of the first electrode on the base substrate;
an orthographic projection of the quantum-well layer on the base substrate covers, and has an area greater than, the orthographic projection of the first type doped semiconductor layer on the base substrate;
an orthographic projection of the second type doped semiconductor layer on the base substrate covers, and has an area greater than, the orthographic projection of the quantum-well layer on the base substrate; and
an orthographic projection of the second electrode on the base substrate covers, and has an area greater than, the orthographic projection of the second type doped semiconductor layer on the base substrate.

12. The method of claim 11, prior to forming the plurality of micro LEDs, further comprising forming a first intermediate substrate by:
providing a growth layer;
forming a second type doped semiconductor material layer on the growth layer;
forming a quantum-well material layer on a side of the second type doped semiconductor material layer away from the growth layer;
forming a first type doped semiconductor material layer on a side of the quantum-well material layer away from the second type doped semiconductor material layer; and
forming a first electrode material layer on a side of the first type doped semiconductor material layer away from the quantum-well material layer.

13. The method of claim 12, subsequent to forming the first intermediate substrate, further comprising:
attaching the first intermediate substrate to a support so that the first electrode material layer is attached to a surface of the support, and the growth layer is on a side of the first electrode material layer away from the support;
removing the growth layer to expose a surface of second type doped semiconductor material layer; and
forming a second electrode material layer on a side of the second type doped semiconductor material layer away from the quantum-well material layer, thereby forming a second intermediate substrate.

14. The method of claim 13, further comprising etching the second intermediate substrate to form the plurality of micro LEDs;
wherein the second intermediate substrate is etched so that:
an orthographic projection of the first type doped semiconductor layer on the support covers, and has an area greater than, an orthographic projection of the first electrode on the support;
an orthographic projection of the quantum-well layer on the support covers, and has an area greater than, the orthographic projection of the first type doped semiconductor layer on the support;
an orthographic projection of the second type doped semiconductor layer on the support covers, and has an area greater than, the orthographic projection of the quantum-well layer on the support; and
an orthographic projection of the second electrode on the support covers, and has an area greater than, the orthographic projection of the second type doped semiconductor layer on the support.

15. The method of claim 14, wherein the support comprises a sacrificial layer, the first intermediate substrate is attached to the support so that the first electrode material layer is attached to a surface of the sacrificial layer, and the growth layer is on a side of the first electrode material layer away from the sacrificial layer;
subsequent to etching the second intermediate substrate, the method further comprises:
etching the sacrificial layer to partially remove the sacrificial layer to form a reduced sacrificial layer, a portion of the sacrificial layer between adjacent micro LEDs of the plurality of micro LEDs is removed, an orthographic projection of the second electrode on the support covers, and has an area greater than, an orthographic projection of the reduced sacrificial layer on the support; and
forming a protection layer covering substantially an entirety of perimeters of the first type doped semiconductor layer, the quantum-well layer, and the second type doped semiconductor layer, and at least partially covering the first electrode and the second electrode.

16. The method of claim 14, further comprising forming a dense metal block on a side of the first electrode away from the support;
wherein the dense metal block is electrically connected to the first electrode; and
the dense metal block has a weight greater than at least twice of a total weight of the first electrode, the first type doped semiconductor layer, the quantum-well layer, the second type doped semiconductor layer, and the second electrode in the respective one of the plurality of micro LEDs; and
a volume of the dense metal block is no more than a half of a total volume of the first electrode, the first type doped semiconductor layer, the quantum-well layer, the second type doped semiconductor layer, and the second electrode in the respective one of the plurality of micro LEDs.

17. The method of claim 16, subsequent to forming the dense metal block, further comprising:
removing the plurality of micro LEDs from the support;
providing a target substrate; and
disposing the plurality of micro LEDs onto the target substrate.

18. The method of claim 17, wherein disposing the plurality of micro LEDs onto the target substrate comprises:
providing a guide plate over the target substrate, the guide plate having a plurality of openings respectively aligned with a plurality of target regions in the target substrate; and
disposing the plurality of micro LEDs on the guide plate to guide the plurality of micro LEDs respectively through the plurality of openings and onto the plurality of target regions.

19. The method of claim 16, wherein the respective one of the plurality of micro LEDs is disposed onto the target substrate so that the dense metal block is in direct contact with a contact pad in a respective one of the plurality of target regions in the target substrate.

20. The method of claim 19, further comprising heating the target substrate to convert the dense metal block into a bonding pad soldered with the contact pad;
wherein the bonding pad is in direct contact with the first electrode and between the first electrode and the target substrate; and
a volume of the bonding pad is no more than a half of a total volume of the first electrode, the first type doped semiconductor layer, the quantum-well layer, the second type doped semiconductor layer, and the second electrode in the respective one of the plurality of micro LEDs.

21. (canceled)

22. (canceled)
